(19) United States
(12) Patent Application Publication
(10) Pub. No.: US 2024/0414983 A1
(43) Pub. Date: Dec. 12, 2024

(54) METHOD OF MANUFACTURING DISPLAY DEVICE AND DISPLAY DEVICE

(71) Applicant: Japan Display Inc., Tokyo (JP)

(72) Inventor: Hiroshi TABATAKE, Tokyo (JP)

(73) Assignee: Japan Display Inc., Tokyo (JP)

(21) Appl. No.: 18/733,914

(22) Filed: Jun. 5, 2024

(30) Foreign Application Priority Data
Jun. 7, 2023 (JP) 2023-094156

(51) Int. Cl. H10K 59/80; H10K 59/12; H10K 59/122

(52) U.S. Cl. CPC H10K 59/873; H10K 59/1201; H10K 59/122

(57) ABSTRACT

According to one embodiment, a method of manufacturing a display device, includes forming a lower electrode, forming an inorganic insulating layer which covers the lower electrode, forming a partition including a conductive lower part and an upper part on the inorganic insulating layer, forming a resist on the inorganic insulating layer, which is patterned using a photomask comprising an aperture including a pair of first straight portions, a pair of second straight portions, and four arc-shaped corner portions each connecting respective of a first straight portion and a second straight portion adjacent to each other, and forming a rib including a pixel aperture that overlaps the lower electrode by removing a part of the inorganic insulating layer, which is exposed from the resist.

### CROSS-REFERENCE TO RELATED APPLICATION

This application is based upon and claims the benefit of priority from Japanese Patent Application No. 2023-094156, filed Jun. 7, 2023, the entire contents of which are incorporated herein by reference.

### FIELD

Embodiments described herein relate generally to a method of manufacturing a display device and a display device.

### BACKGROUND

In recent years, display devices in which organic light-emitting diodes (OLEDs) are applied as display elements have been put to practical use. This display element comprises a lower electrode, an organic layer covering the lower electrode, and an upper electrode covering the organic layer.

In manufacturing such display devices as described above, there is a need for a technology to suppress the degradation of reliability.

### BRIEF DESCRIPTION OF THE DRAWINGS

FIG. 1 is a diagram showing a configuration example of a display device according to one embodiment.

FIG. 2 is a diagram showing an example of layout of subpixels.

FIG. 3 is a cross-sectional view schematically showing the display device taken along line III-III in FIG. 2.

FIG. 4 is a plan view illustrating schematically showing a planer shape of a pixel aperture according to the embodiment.

FIG. 5 is a diagram showing an example of a configuration which can be applied to a rib having pixel apertures of the embodiment.

FIG. 6 is a plan view schematically showing a part of a photomask of the embodiment.

FIG. 7 is a plan view schematically showing a part of the photomask of the embodiment.

FIG. 8 is a diagram illustrating a processing step of forming pixel apertures in a manufacturing method according to the embodiment.

FIG. 9 is a diagram illustrating a processing step of forming pixel apertures in the manufacturing method according to the embodiment.

FIG. 10 is a plan view schematically showing a part of a photomask used in a manufacturing method according to a comparative example.

FIG. 11 is a diagram illustrating a processing step of forming pixel apertures in the manufacturing method according to the comparative example.

FIG. 12 is a cross-sectional view schematically showing a part of a display device manufactured by the manufacturing method according to the comparative example.

### DETAILED DESCRIPTION

In general, according to one embodiment, a method of manufacturing a display device, includes forming a lower electrode, forming an inorganic insulating layer which covers the lower electrode, forming a partition including a conductive lower part and an upper part including an end portion protruding from a side surface of the lower part, on the inorganic insulating layer, forming a resist on the inorganic insulating layer, which is patterned using a photomask comprising an aperture including a pair of first straight portions extending in a first direction, a pair of second straight portions extending in a second direction intersecting the first direction, and four arc-shaped corner portions each connecting each respective of a first straight portion and a second straight portion adjacent to each other, and forming a rib including a pixel aperture that overlaps the lower electrode by removing a part of the inorganic insulating layer, which is exposed from the resist.

According to another embodiment, a display device comprises a lower electrode, a rib including a pixel aperture which overlaps the lower electrode, a partition including a conductive lower part disposed on the rib and an upper part including having an end portion protruding from a side surface of the lower part, a stacked film including an organic layer in contact with the lower electrode via the pixel aperture and an upper electrode which covers the organic layer, and a sealing layer which covers the stacked film. The rib includes an end portion having a tapered shape over an entire circumference of the pixel apertures.

Embodiments will now be described with reference to the accompanying drawings.

Note that the disclosure is merely an example, and proper changes in keeping with the spirit of the invention, which are easily conceivable by a person of ordinary skill in the art, come within the scope of the invention as a matter of course. In addition, in some cases, in order to make the description clearer, the drawings show schematic illustration rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

Further, in order to make the descriptions more easily understandable, some of the drawings illustrate an X axis, a Y axis and a Z axis orthogonal to each other. A direction along the X axis is referred to as a first direction, a direction along the Y axis is referred to as a second direction and direction along the Z axis is referred to as a third direction. The third direction Z is a direction normal to the plane (X-Y plane) that includes the first direction X and the second direction Y. Further, viewing the various elements parallel to the third direction Z is referred to as plan view.

The display devices of the embodiments are each an organic electroluminescent display device comprising an organic light emitting diode (OLED) as a display element, and can be mounted on various types of electronic devices such as televisions, personal computers, in-vehicle devices, tablet terminals, smartphones, mobile phones, wearable terminals and the like.

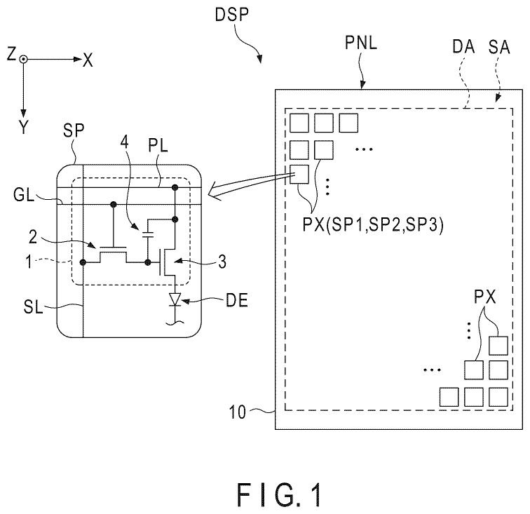

FIG. 1 is a diagram showing a configuration example of a display device DSP according to the present embodiment. The display device DSP comprises a display panel PNL including an insulating substrate 10. The display panel PNL has a display area DA for displaying images and a peripheral area SA around the display area DA. The substrate 10 may be glass or a flexible resin film.

In the present embodiment, the shape of the substrate 10 in plan view is rectangular. However, the shape of the substrate 10 in plan view is not limited to a rectangle, and may be other shapes such as a square, circle, or oval.

The display area DA comprises a plurality of pixels PX arranged in a matrix in a first direction X and a second direction Y. The pixel PX includes a plurality of subpixels SP. In one example, the pixel PX includes a blue subpixel SP1, a green subpixel SP2, and a red subpixel SP3. Note that the pixel PX may include a subpixel SP of another color, such as white, together with or instead of any of the subpixels SP1, SP2, and SP3.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are switching elements configured by, for example, thin-film transistors.

A gate electrode of the pixel switch 2 is connected to a scanning line GL. One of source and drain electrodes of the pixel switch 2 is connected to a signal line SL, and the other is connected to a gate electrode of the drive transistor 3 and the capacitor 4. In the drive transistor 3, one of source and drain electrodes is connected to a power line PL and the capacitor 4, and the other is connected to the display element DE.

Note that the configuration of the pixel circuit 1 is not limited to the illustrated example. For example, the pixel circuit 1 may comprise more thin-film transistors and capacitors.

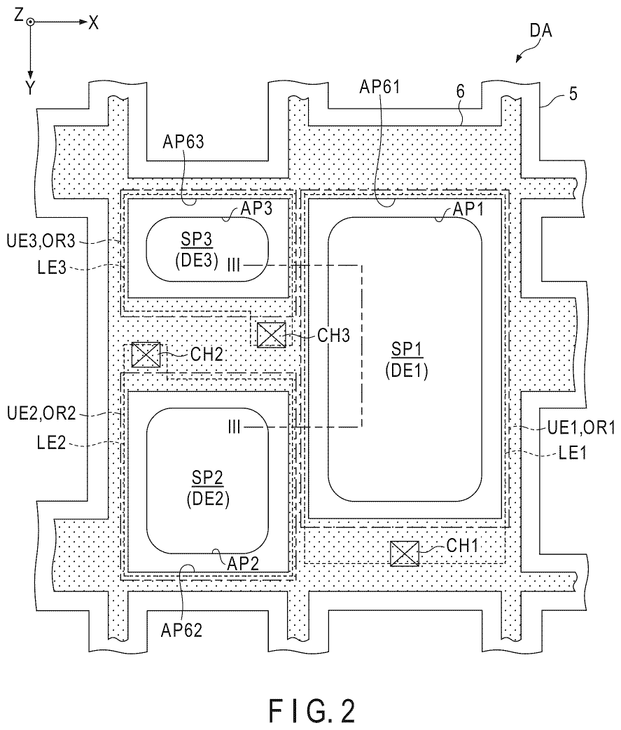

FIG. 2 is a schematic plan view showing an example layout of the subpixels SP1, SP2, and SP3. In the example of FIG. 2, the subpixels SP2 and SP3 are aligned with the subpixel SP1 in the first direction X, respectively. Furthermore, the subpixel SP2 and the subpixel SP3 are aligned in the second direction Y.

In the case where the subpixels SP1, SP2, and SP3 have such a layout, a row in which the subpixels SP2 and SP3 are arranged alternately in the second direction Y and a row in which a plurality of subpixels SP1 are arranged repeatedly in the second direction Y are formed in the display area DA. These rows are arranged alternately in the first direction X. Note that the layout of the subpixels SP1, SP2, and SP3 is not limited to the example in FIG. 2.

A rib 5 is arranged in the display area DA. The rib 5 has pixel apertures AP1, AP2, and AP3 in the subpixels SP1, SP2, and SP3, respectively. In the example of FIG. 2, the pixel aperture AP1 is larger than the pixel aperture AP2, and the pixel aperture AP2 is larger than the pixel aperture AP3.

The subpixel SP1 comprises a lower electrode LE1, an upper electrode UE1, and an organic layer OR1 that overlap with the pixel aperture AP1, respectively. The subpixel SP2 comprises a lower electrode LE2, an upper electrode UE2, and an organic layer OR2 that overlap with the pixel aperture AP2, respectively. The subpixel SP3 comprises a lower electrode LE3, an upper electrode UE3, and an organic layer OR3 that overlap with the pixel aperture AP3, respectively.

A portion of the lower electrode LE1, the upper electrode UE1, and the organic layer OR1 that overlaps with the pixel aperture AP1 configures a display element DE1 of the subpixel SP1. A portion of the lower electrode LE2, the upper electrode UE2, and the organic layer OR2 that overlaps with the pixel aperture AP2 configures a display element DE2 of the subpixel SP2. A portion of the lower electrode LE3, the upper electrode UE3, and the organic layer OR3 that overlaps with the pixel aperture AP3 configures a display element DE3 of the subpixel SP3. The display elements DE1, DE2, and DE3 may further include a cap layer as described later. The rib 5 surrounds each of these display elements DE1, DE2, and DE3.

The lower electrode LE1 is connected to the pixel circuit 1 of the subpixel SP1 (see FIG. 1) through a contact hole CH1. The lower electrode LE2 is connected to the pixel circuit 1 of the subpixel SP2 through a contact hole CH2. The lower electrode LE3 is connected to the pixel circuit 1 of the subpixel SP3 through a contact hole CH3.

Above the rib 5 is arranged a partition 6. The partition 6 overlaps with the rib 5 overall and has the same planar shape as the rib 5. That is, the partition 6 has apertures AP61, AP62, and AP63 in the subpixels SP1, SP2, and SP3, respectively. In other terms, the rib 5 and the partition 6 are arranged between the display elements DE1, DE2, and DE3 and are lattice-shaped in plan view.

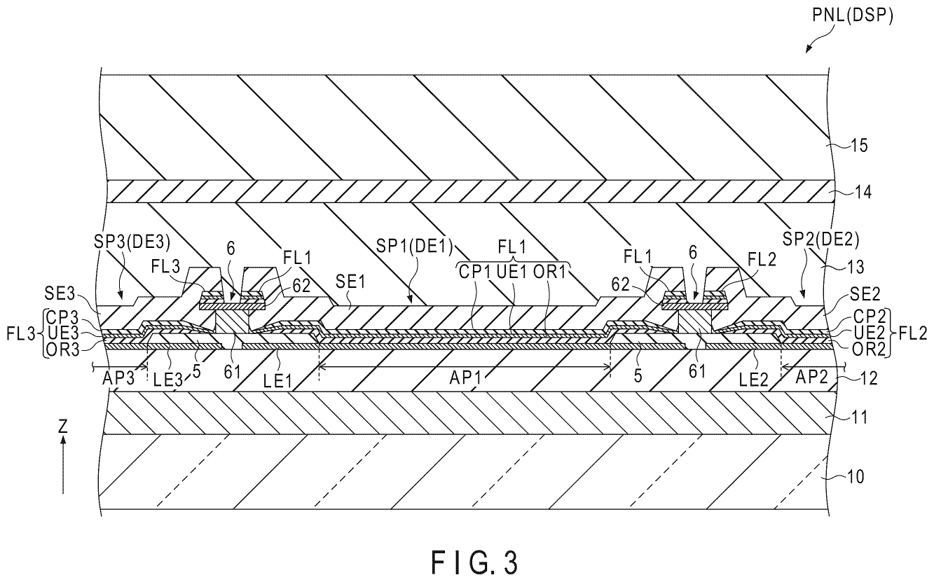

FIG. 3 is a schematic cross-sectional view of the display panel PNL (display device DSP) taken along line III-III in FIG. 2. A circuit layer 11 is arranged on the substrate 10 described above. The circuit layer 11 includes various circuits and wiring, such as the pixel circuit 1, the scanning line GL, the signal line SL, and the power line PL shown in FIG. 1.

The circuit layer 11 is covered by an organic insulating layer 12. The organic insulating layer 12 functions as a planarization film to flatten an unevenness caused by the circuit layer 11. Although not shown in the cross section of FIG. 3, the contact holes CH1, CH2, and CH3 described above are provided in the organic insulating layer 12.

The lower electrodes LE1, LE2, and LE3 are arranged on the organic insulating layer 12. The rib 5 is arranged on the organic insulating layer 12 and the lower electrodes LE1, LE2, and LE3. End portions of the lower electrodes LE1, LE2, and LE3 are covered by the rib 5.

The partition 6 includes a conductive lower part 61 arranged on the rib 5 and an upper part 62 arranged on the lower part 61. The upper part 62 has a greater width than the lower part 61. This causes both end portions of the upper part 62 to protrude beyond the side surfaces of the lower part 61. Such a shape of the partition 6 is referred to as overhanging.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 are in contact with the side surfaces of the lower part 61 of the partition 6.

In the example of FIG. 3, a cap layer CP1 is arranged on the upper electrode UE1, a cap layer CP2 is arranged on the upper electrode UE2, and a cap layer CP3 is arranged on the upper electrode UE3. The cap layers CP1, CP2, and CP3 serve as optical adjustment layers that improve the efficiency of extracting light emitted by the organic layers OR1, OR2, and OR3, respectively.

In the following description, a multilayer including the organic layer OR1, the upper electrode UE1, and the cap layer CP1 is referred to as a stacked film FL1, a multilayer including the organic layer OR2, the upper electrode UE2, and the cap layer CP2 is referred to as a stacked film FL2, and a multilayer including the organic layer OR3, the upper electrode UE3, and the cap layer CP3 is referred to as a stacked film FL3.

A part of the stacked film FL1 is located on the upper part 62. This part is separated from the part of the stacked film FL1, which is located below the partition 6 (the part constituting the display element DE1). Similarly, a part of the stacked film FL2 is located on the upper part 62, and this part thereof is separated from the part of the stacked film FL2, which is located below the partition 6 (the part constituting the display element DE2). Further, a part of the stacked film FL3 is located on the upper part 62, and this part is separated from the part of the stacked film FL3, which is located below the partition 6 (the part constituting the display element DE3).

Sealing layers SE1, SE2, and SE3 are arranged in the subpixels SP1, SP2, and SP3, respectively. The sealing layer SE1 continuously covers the stacked film FL1 and the side surface of the partition 6 around the subpixel SP1. The sealing layer SE2 continuously covers the stacked film FL2 and the side surface of the partition 6 around the subpixel SP2. The sealing layer SE3 continuously covers the stacked film FL3 and the side surface of the partition 6 around and the subpixel SP3.

In the example of FIG. 3, the stacked film FL1 and the sealing layer SE1 on the partition 6 between the subpixels SP1 and SP2 are separated from the stacked film FL2 and the sealing layer SE2 on the partition 6. Further, the stacked film FL1 and the sealing layer SE1 on the partition 6 between the subpixels SP1 and SP3 are separated from the stacked film FL3 and the sealing layer SE3 on the partition 6.

The sealing layers SE1, SE2, and SE3 are covered by a resin layer 13. The resin layer 13 is covered by a sealing layer 14. The sealing layer 14 is covered by a resin layer 15. The resin layers 13 and 15 and the sealing layer 14 are continuously provided at least over the entire display area DA, and some of them extend to the peripheral area SA.

Cover members such as polarizers, touch panels, protective films, or cover glasses may be further arranged above the resin layer 15. Such cover members may be adhered to the resin layer 15 via an adhesive layer, such as an optical clear adhesive (OCA).

The organic insulating layer 12 is formed of an organic insulating material. The rib 5 and the sealing layers 14, SE1, SE2, and SE3 are formed of an inorganic insulating material such as silicon nitride (SiNx), silicon oxide (Siox), silicon oxynitride (SiON), or aluminum oxide (Al₂O₃). In one example, the rib 5 is formed of silicon oxynitride, and the sealing layers 14, SE1, SE2, and SE3 are formed of silicon nitride. The resin layers 13 and 15 are formed of a resin material (organic insulating material) such as epoxy resin or acrylic resin.

The lower electrodes LE1, LE2, and LE3 have a reflective layer formed of silver (Ag), for example, and a pair of conductive oxide layers covering the upper and lower surfaces of the reflective layer, respectively. Each conductive oxide layer can be formed of a transparent conductive oxide, such as indium tin oxide (ITO), indium zinc oxide (IZO), or indium gallium zinc oxide (IGZO).

The upper electrodes UE1, UE2, and UE3 are formed of a metallic material, such as an alloy of magnesium and silver (MgAg). For example, the lower electrodes LE1, LE2, and LE3 correspond to anodes, and the upper electrodes UE1, UE2, and UE3 correspond to cathodes.

The organic layers OR1, OR2, and OR3, for example, have a stacked structure of a hole injection layer, a hole transport layer, an electron blocking layer, a light-emitting layer, a hole blocking layer, an electron transport layer, and an electron injection layer. The organic layers OR1, OR2, and OR3 may have a so-called tandem structure including multiple light-emitting layers.

The cap layers CP1, CP2, and CP3, for example, have a stacked structure of a plurality of transparent thin films. The plurality of thin films may include thin films formed by inorganic materials and thin films formed by organic materials. The plurality of thin films have different refractive indices. The materials of these thin films are different from the materials of the upper electrodes UE1, UE2, and UE3 and are also different from the materials of the sealing layers SE1, SE2, and SE3. Note that at least one of the cap layers CP1, CP2, and CP3 may be omitted.

The lower part 61 of the partition 6 is formed, for example, by aluminum. The lower part 61 may be formed of an aluminum alloy such as aluminum-neodymium alloy (AlNd), aluminum-yttrium alloy (AlY), and aluminum-silicon alloy (AlSi), or may have a stacked structure of an aluminum layer and an aluminum alloy layer. Furthermore, the lower part 61 may have a bottom layer formed of a metallic material different from aluminum or aluminum alloy under the aluminum or aluminum alloy layer. As the metallic material forming such a bottom layer, molybdenum (Mo), titanium nitride (TiN), molybdenum-tungsten alloy (MoW), or molybdenum-niobium alloy (MoNb) can be used, for example.

For example, the upper part 62 of the partition 6 has a stacked structure with a lower layer formed of a metallic material and an upper layer formed of a conductive oxide. For example, titanium, titanium nitride, molybdenum, tungsten, molybdenum-tungsten alloy, or molybdenum-niobium alloy can be used as the metallic material forming the lower layer. For example, ITO or IZO can be used as the conductive oxide forming the upper layer. Note that the upper part 62 may have a monolayer structure of metallic material.

A common voltage is supplied to the partition 6. This common voltage is supplied to the upper electrodes UE1, UE2, and UE3, which are in contact with the side surfaces of the lower part 61, respectively. The lower electrodes LE1, LE2, and LE3 are supplied with a pixel voltage through the pixel circuit 1 that the subpixels SP1, SP2, and SP3 have respectively.

The organic layers OR1, OR2, and OR3 emit light according to the application of voltage. Specifically, when a potential difference is formed between the lower electrode LE1 and the upper electrode UE1, the light-emitting layer of the organic layer OR1 emits light in a blue wavelength range. When a potential difference is formed between the lower electrode LE2 and the upper electrode UE2, the light-emitting layer of the organic layer OR2 emits light in a green wavelength range. When a potential difference is formed between the lower electrode LE3 and the upper electrode UE3, the light-emitting layer of the organic layer OR3 emits light in a red wavelength range.

As another example, the light-emitting layers of the organic layers OR1, OR2, and OR3 may emit light of the same color (for example, white). In this case, the display device DSP may be provided with a color filter that converts the light emitted by the light-emitting layers into light of a color corresponding to the subpixels SP1, SP2, and SP3. The display device DSP may also be provided with a layer containing quantum dots that are excited by the light emitted by the light-emitting layer to generate light of a color corresponding to the subpixels SP1, SP2, and SP3.

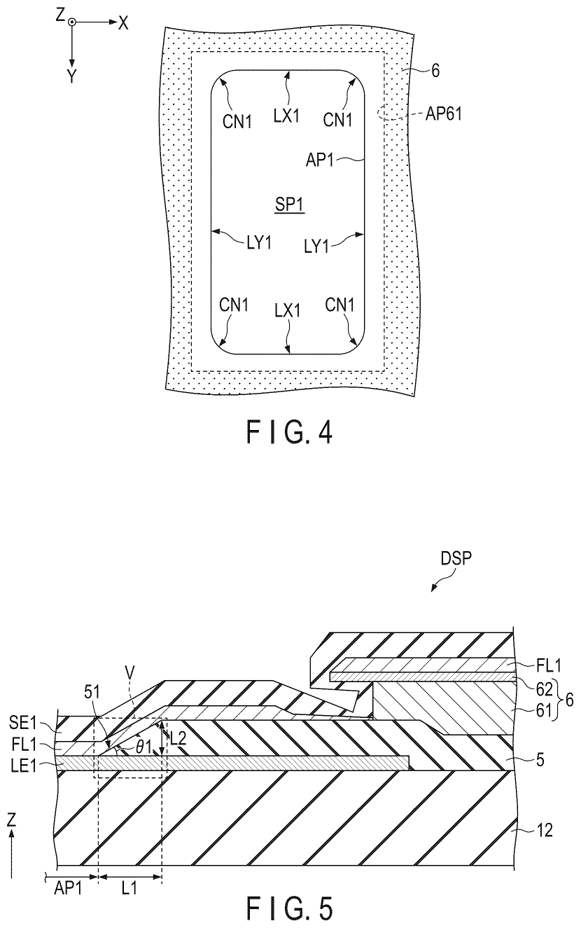

FIG. 4 is a schematic plan view schematically showing a planer shape of the pixel aperture AP1 of the subpixel SP1. Note that in this figure, only the pixel aperture AP1 of the subpixel SP1 is shown, but the pixel aperture AP2 of the subpixel SP2 and the pixel aperture AP3 of the subpixel SP3 have a planar shape similar thereto.

As shown in FIG. 4, the pixel aperture AP1 includes a pair of first straight portions LX1 extending along the first direction X, a pair of second straight portions LY1 extending in the second direction Y, and four arc-shaped corner portions CN1. Each of the corner portions CN1 connects the first straight portion LX1 and the second straight portion LY1 adjacent to each other. As will be described in detail later, the pixel aperture AP1 has a planar shape similar to that of a mask aperture formed in a photomask used for patterning a resist to be displaced when forming the pixel aperture AP1.

Note that the aperture AP61 of the partition 6 surrounding the pixel aperture AP1 is rectangular in shape, as shown in FIG. 4. That is, the pixel aperture AP1 of the subpixel SP1 and the aperture AP61 of the partition 6 surrounding the subpixel SP1 have planar shapes different from each other.

FIG. 5 is a diagram showing an example of a structure that can be applied to the rib 5 with pixel apertures. Not that in this figure, the rib 5 with the pixel aperture AP1 is shown, but a similar structure can be applied to the rib 5 with the pixel aperture AP2 of the subpixel SP2 and the rib 5 with the pixel aperture AP3 of the subpixel SP3.

In the example of FIG. 5, the end portion of the lower electrode LE1 is located below the lower part 61. With this configuration, a step portion of the rib 5 caused by the lower electrode LE1 is covered by the lower part 61.

Although its detailed illustration is omitted in FIG. 5, the side surface of the lower part 61 is in contact with the upper electrode UE1 contained in the stacked film FL1, as described above. Note that the organic layer OR1 contained in the stacked film FL1 is not in contact with the side surface of the lower part 61, but is entirely covered by the upper electrode UE1. Further, the cap layer CP1 contained in the stacked film FL1 may be or may not be brought into contact with the side surface of the lower part 61.

As shown in an area V surrounded by dashed lines in FIG. 5, the end portion 51 of the rib 5 near the pixel aperture AP1 is gently inclined at an angle θ1 with respect to the upper surface of the lower electrode LE1. In other words, the end portion 51 of the rib 5 has a tapered shape (more particularly, a forward tapered shape in which the width of the rib 5 decreases as the location is upward along the third direction Z).

Note that the angle θ1 (more particularly, an inclination angle θ1 of the end portion 51 with respect to the upper surface of the lower electrode LE1) should desirably be less than 45°. In other words, a horizontal length L1 of the end portion 51 of the rib 5 should desirably be greater than that of a film thickness L2 of the rib 5. According to such a structure, it is possible to prevent the stacked film FL1 (the upper electrode UE1, the organic layer OR1, and the cap layer CP1) from being cut in step or the sealing layer SE1 from being cut (defects such as cracks made in the sealing layer SE1) at the end portion 51 of the rib 5 near the pixel aperture AP1.

The end portion of the rib 5 has the configuration shown in FIG. 5 over the entire circumference of the pixel aperture AP1. That is, the end portion 51 of the rib 5 has the configuration shown in FIG. 5 in each of the vicinity of the first straight portion LX1, the vicinity of the second straight portion LY1, and the vicinity of the corner portion CN1 of the pixel aperture AP1. Note that as described above, the end portion 51 of the rib 5 has a similar configuration in the entire circumference of the pixel aperture AP2 of the subpixel SP2 and the entire circumference of the pixel aperture AP3 of the subpixel SP3.

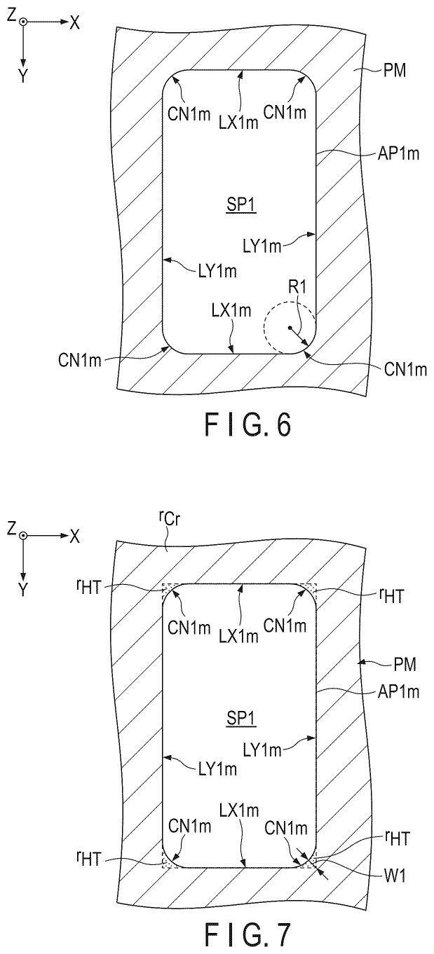

FIG. 6 is a plan view schematically showing a part of a photomask PM for patterning a resist to be disposed when forming the pixel apertures. The photomask PM is formed, for example, of chromium (Cr). Note that in this figure, the part of the photomask PM, which corresponds to the pixel aperture AP1 of the subpixel SP1 (that is, the part corresponding to the pixel aperture AP1 shown in FIG. 4) is shown, but the part corresponding to the pixel aperture AP2 of the subpixel SP2 and the part corresponding to the pixel aperture AP3 of the subpixel SP3 are similar thereto.

As shown in FIG. 6, the photomask PM includes a mask aperture AP1m corresponding to the pixel aperture AP1. The mask aperture AP1m has a pair of first straight portions LX1m extending in the first direction X, a pair of second straight portions LY1m extending in the second direction Y, and four arc-shaped corner portions CN1m. Each of the corner portions CN1m connects a respective pair of the first straight portion LX1m and the second straight portion LY1m adjacent to each other.

In order to realize the configuration shown in FIG. 5, that is, a configuration in which the length L1 of the end portion 51 of the rib 5 is greater than the film thickness L2 of the rib 5 (in other words, a configuration in which the end portion 51 of the rib 5 is gently inclined at an angle of 45° or less with respect to the upper surface of the lower electrode LE1), the radius R1 of curvature of each of the corner portions CN1m should preferably be set to a value of 3 μm or more. More preferably, the radius R1 of curvature of each of the corner portions CN1m should be set to a value of 5 μm or more. With this configuration, it is possible to realize the configuration shown in FIG. 5, as will be described in detail later.

FIG. 6 shows, as an example case, that each of the corner portions CN1m of the mask aperture AP1m has an R surface (curved surface) chamfered by R, but each of the corner portions CN1m may as well have a C surface chamfered by C (, which is such a surface that the first straight portion LX1m and the second straight portion LY1m are connected to each other by a straight portion inclined at 45° with respect to the first straight portion LX1m or the second straight portion LY1m, which is set along that straight portion).

The value (radius of curvature) of the R surface and the value (dimension) of the C surface are set based on the height of the partition 6 (the lower part 61 and the upper part 62) surrounding the pixel aperture AP1 and the distance from the aperture AP61 of the partition 6 to the pixel aperture AP1.

FIG. 7 is a plan view schematically showing a part of another photomask PM for patterning a resist to be placed when forming the pixel apertures. The photomask PM shown in FIG. 7 is different from the photomask PM shown in FIG. 6 in that it includes a first region r_{Cr} where a chromium film formed of chromium is disposed and second regions r_{HT} wherein halftone films are disposed in place of the chromium film described above.

The shaded area in FIG. 7 corresponds to the first region r_{Cr}, and the dotted areas in FIG. 7 corresponds to the second regions r_{HT}. Each of the second regions r_{HT} is a region corresponding to each of the corner portions CN1m of the mask aperture AP1m, as shown in FIG. 7. While the light transmittance of the first region r_{Cr}, where the chromium film is placed, is 0%, the light transmittance of the second region r_{HT}, where the halftone film is placed, is approximately 30% to 40%. The resist placed at the position overlapping the mask aperture AP1m is removed by patterning, the resist placed at the position overlapping the first region r_{Cr} is not removed by patterning, and the resists placed at the position overlapping each of the second regions r_{HT} are partially removed by patterning.

In order to realize the configuration shown in FIG. 5, that is, a configuration in which the length L1 of the end portion 51 of the rib 5 is greater than the film thickness L2 of the rib 5 (in other words, a structure in which the end portion 51 of the rib 5 is gently inclined at an angle of 45° or less with respect to the upper surface of the lower electrode LE1), the width W1 of the second region r_{HT}, where the halftone film shown in FIG. 7 is placed, should preferably be set to a value of 4 μm or more. With this structure, the configuration shown in FIG. 5 can be realized in a way similar to the case where the photomask PM shown in FIG. 6 is used.

Note that the above-described structure is similar to that of the photomask PM shown in FIG. 6 in the point that each of the corner portions CN1m of the mask aperture AP1m may as well be R-chamfered R surface (curved surface) or C-chamfered C surface.

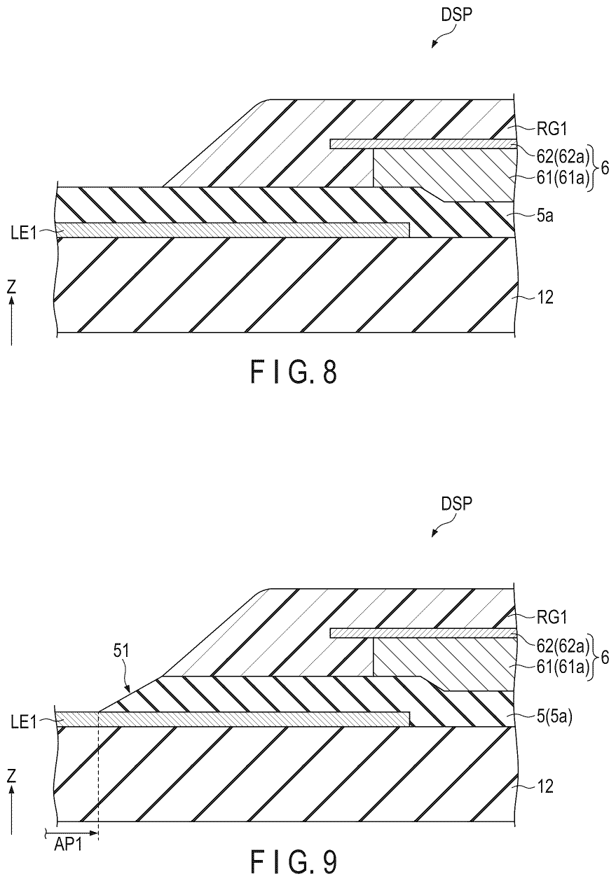

Next, with reference to FIGS. 8 and 9, the process of forming the pixel aperture AP1 in a manufacturing method of this embodiment will be described. In these figures, how the pixel aperture AP1 of the subpixel SP1 is formed is illustrated, but in the same process, the pixel aperture AP2 of the subpixel SP2 and the pixel aperture AP3 of the subpixel SP3 as well are formed.

Although detailed illustrations thereof are omitted here, in the manufacturing method of the display device DSP, first, a circuit layer 11 and an organic insulating layer 12 are formed on a substrate 10. Next, lower electrodes LE1, LE2, and LE3 are formed on the organic insulating layer 12. Then, an inorganic insulating layer 5a to be processed into the rib 5 is formed to cover the lower electrodes LE1, LE2, and LE3 entirely. Further, a conductive first layer 61a to be processed into the lower part 61 is formed on the inorganic insulating layer 5a, and a second layer 62a to be processed into the upper part 62 is formed on the first layer 61a.

Subsequently, the first layer 61a and the second layer 62a are then patterned. This patterning step includes etching of the second layer 62a into the shape of the upper part 62 and etching of the first layer 61a into the shape of the lower part 61. By these etching steps, the partition 6 including the lower part 61 and the upper part 62 is formed on the inorganic insulating layer 5a.

After the formation of the partition 6, a resist RG1 patterned to the planar shape of the rib 5 via the photomask PM shown in FIG. 6 or FIG. 7 is placed on the inorganic insulating layer 5a, as shown in FIG. 8. By using the photomask PM shown in FIG. 6 or FIG. 7, the resist RG1 is patterned into such a shape that is sloped near the portion where the pixel aperture AP1 is formed, as shown in FIG. 8. Although not shown here, the shape of the resist RG1 near the portion where the pixel aperture AP2 is formed and that near the portion where the pixel aperture AP3 as well are formed in a similar fashion.

After that, as shown in FIG. 9, the portion of the inorganic insulating layer 5a to be processed into the rib 5, which is exposed from the resist RG1, is removed by etching. With this configuration, as shown in FIG. 9, the rib 5 including the pixel aperture AP1 (and pixel apertures AP2 and AP3) and the end portion 51 having a gently tapered shape is formed.

From this on, the processing steps for forming the display elements DE1, DE2, and DE3 are carried out in sequence. With this configuration, a display device DSP having the configuration shown in FIG. 5 is manufactured. That is, such a display device DSP is manufactured that has a structure in which the length L1 of the end portion 51 of the rib 5 is greater than the film thickness L2 of the rib 5 over the entire circumference of the pixel aperture AP1 (and the pixel apertures AP2 and AP3) (in other words, a structure in which the end portion 51 of the rib 5 is gently inclined at an angle of 45° or less with respect to the upper surface of the lower electrode LE1).

In the following, advantageous effects of the manufacturing method and the display device DSP of the embodiment will be explained using comparative examples. Note that the comparative examples are intended to illustrate some of the effects that can be achieved by the manufacturing method and display device DSP according to the present embodiment, and effects common to the present embodiment and the comparative examples are not excluded from the scope of the present invention.

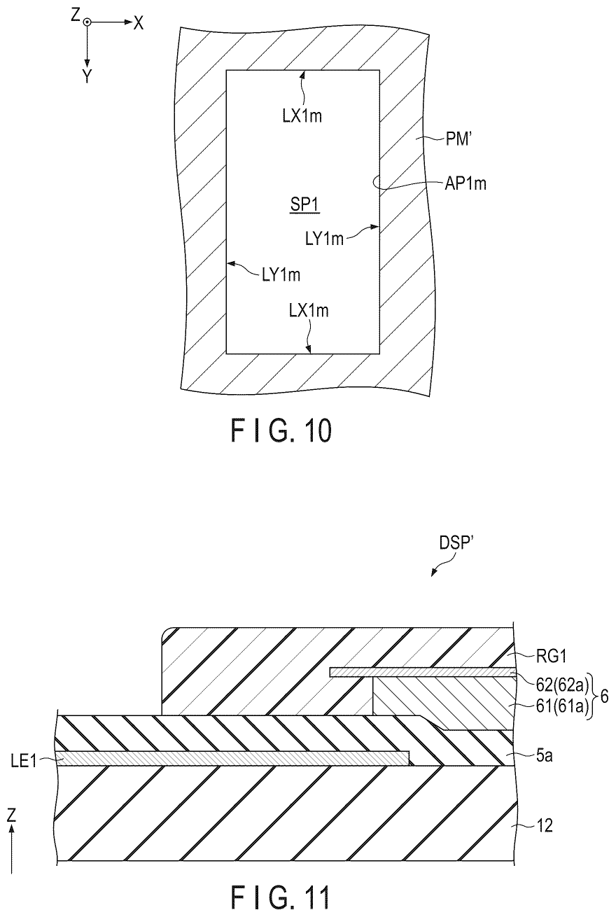

FIG. 10 is a plan view schematically showing a part of the photomask PM′ used in the manufacturing method according to the comparative example. Note that in this figure, the part of the photomask PM′, which corresponds to the pixel aperture AP1 of the subpixel SP1 is shown, but the part corresponding to the pixel aperture AP2 of the subpixel SP2 and the part corresponding to the pixel aperture AP3 of the subpixel SP3 are similar thereto.

The photomask PM′ of the comparative example is different from the photomask PM of the present embodiment in that the planar shape of the mask aperture AP1m is a rectangle with a pair of first straight portions LX1m extending in the first direction X and a pair of second straight portions LY1m extending in the second direction Y, as shown in FIG. 10.

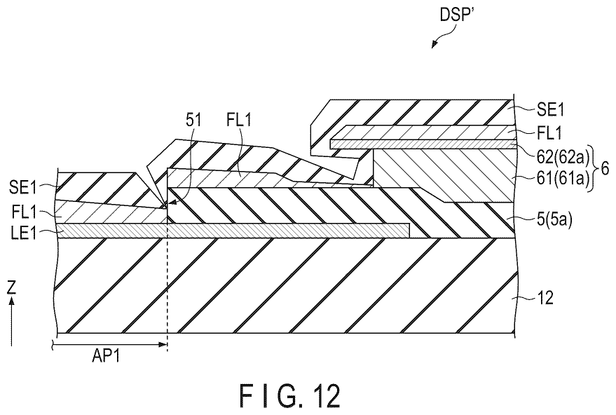

FIG. 11 is a diagram illustrating the processing step of forming a pixel aperture AP1 in the manufacturing method according to the comparative example. FIG. 12 is a cross-sectional view schematically showing a part of a display device DSP′ manufactured by the manufacturing method according to the comparative example.

In the manufacturing method of the comparative example, when the partition 6 is formed by a process similar to that of the manufacturing method of this embodiment, the resist RG1 patterned by using the photomask PM′ shown in FIG. 10 is placed on the inorganic insulating layer 5a. With this configuration, the resist RG1, which is mainly disposed at the position overlapping the vicinity of the corners of the rectangular mask aperture AP1m, is patterned into a steep shape and not in an inclined shape, as shown in FIG. 11. Therefore, the end portion 51 of the rib 5 formed as a result of patterning using the resist RG1 as a mask can as well be a steep shape.

According to this, as shown in FIG. 12, there is a possibility that the stacked film FL1 (the organic layer OR1, the upper electrode UE1, and the cap layer CP1) deposited on the lower electrode LE1 in the process of forming the display element DE1 will be cut in step at the end portion 51 of the rib 5. Further, as shown in FIG. 12, there is a possibility that the sealing layer SE1 covering the stacked film FL1 may break at the end portion 51 of the rib 5 (that is, defects such as cracks may occur in the sealing layer SE1). Such cutting in step of the stacked film FL1 or a defect in the encapsulation layer SE1 may lower the luminance of the display device or reduce the resistance to moisture of the display device, which reduces the reliability of the display device.

In contrast, in the manufacturing method of this embodiment, the resist RG1 is patterned by using the photomask PM shown in FIG. 6 or FIG. 7, and the resist RG1 placed in the position overlapping the vicinity of the corner portion CN1m of the mask aperture AP1m can be patterned into an inclined shape (See FIG. 8). With this structure, the end portion 51 of the rib 5 formed as a result of patterning using the resist RG1 as a mask can be formed into an inclined shape over the entire circumference of the pixel aperture AP1, as shown in FIG. 9. According to this, it is possible to prevent the stacked film FL1 (the upper electrode UE1, the organic layer OR1, and the cap layer CP1) from being cut in step and the sealing layer SE1 from being cut (defects such as cracks occurring in the sealing layer SE1) at the end portion 51 of the rib 5. That is, the degradation in reliability of the display device can be suppressed.

According to one embodiment described above, it is possible to provide a method for manufacturing a display device which can suppress a decrease in reliability and such a display device itself.

While certain embodiments and variations have been described, these embodiments and variations have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a display device, comprising:
forming a lower electrode;
forming an inorganic insulating layer which covers the lower electrode;
forming a partition including a conductive lower part and an upper part including an end portion protruding from a side surface of the lower part, on the inorganic insulating layer;
forming a resist on the inorganic insulating layer, which is patterned using a photomask comprising an aperture including a pair of first straight portions extending in a first direction, a pair of second straight portions extending in a second direction intersecting the first direction, and four arc-shaped corner portions each connecting each respective of a first straight portion and a second straight portion adjacent to each other; and
forming a rib including a pixel aperture that overlaps the lower electrode by removing a part of the inorganic insulating layer, which is exposed from the resist.

2. The method of claim 1, wherein
the rib includes an end portion having a tapered shape over an entire circumference of the pixel aperture.

3. The method of claim 2, wherein
the end portion of the rib has an inclined angle of 45° or less.

4. The method of claim 1, wherein
a radius of curvature of each of the corner portions is 3 μm or more.

5. The method of claim 1, wherein
the photomask comprises a halftone film disposed in a region corresponding to each of the corner portions and a chromium film disposed in a region other than those corresponding to each of the corner portions and the aperture.

6. The method of claim 5, wherein
a width of the halftone film is 4 μm or more.

7. The method of claim 1, further comprising:
forming an organic layer which covers the lower electrode and emits light in response to application of voltage; and
forming an upper electrode which covers the organic layer and is in contact with the lower part.

8. The method of claim 7, further comprising:
forming a sealing layer that continuously covers a stacked film including the organic layer and the upper electrode and the partition.

9. A display device comprising:
a lower electrode;
a rib including a pixel aperture which overlaps the lower electrode;
a partition including a conductive lower part disposed on the rib and an upper part including having an end portion protruding from a side surface of the lower part;
a stacked film including an organic layer in contact with the lower electrode via the pixel aperture and an upper electrode which covers the organic layer; and
a sealing layer which covers the stacked film, wherein
the rib includes an end portion having a tapered shape over an entire circumference of the pixel apertures.

10. The display device of claim 9, wherein
the end portion of the rib has an inclined angle of 45° or less.
